(19) United States
(12) Patent Application Publication
(10) Pub. No.: US 2022/0254759 A1
(43) Pub. Date: Aug. 11, 2022

(54) Light Emission System with MicroLED Device Isolation

(71) Applicant: Raxium, Inc., Fremont, CA (US)

(72) Inventors: Gang He, Cupertino, CA (US); Li Yan, Dublin, CA (US); Michael Joseph Cich, San Jose, CA (US)

(21) Appl. No.: 17/576,300

(22) Filed: Jan. 14, 2022

Related U.S. Application Data
(60) Provisional application No. 63/137,355, filed on Jan. 14, 2021.

(51) Int. Cl. H01L 25/075; H01L 33/32; H01L 33/50; H01L 33/00; H01L 33/14

(52) U.S. Cl. CPC H01L 25/0753; H01L 33/32; H01L 2933/0041; H01L 33/005; H01L 33/145; H01L 33/502

(57) ABSTRACT

A light emission system includes an array of micro light-emitting diodes (microLED)s. The array of microLEDs includes a semiconductor substrate, a prep layer formed on at least a portion of the semiconductor substrate, and an active region formed on the prep layer. The array of microLEDs also include a plurality of thick sub-structures forming an array on the active region, and a plurality of thin sub-structures formed on the active region, each one of the thin sub-structures being located between each adjacent pair of thick substructures. Each one of the thick sub-structures defines a shape and size of a corresponding one of the microLEDs. Each one of the thin sub-structures is configured for preventing mobility of free electron carriers therethrough to electrically isolate each one of the thick sub-structures from every other one of the thick sub-structures. Further, the plurality of microLEDs share the active region.

### CROSS REFERENCE TO RELATED APPLICATIONS

This application claims priority to U.S. Provisional Application Ser. No. 63/137,355 filed Jan. 14, 2021, the entire content of which is incorporated herein by reference.

### BACKGROUND

Aspects of the present disclosure generally relate to light emitting structures, such as the structures of light emitting diodes used in various types of displays and other devices.

Increasing numbers of picture elements (or pixels) in light emitting devices and displays may improve a user experience and enable new applications. However, it is challenging to increase the number or the density of light emitting elements forming the pixels. A reduction in the size of light emitting diodes (LEDs) enables an increase in both count and density light emitting elements forming the pixels.

Recent developments in LED manufacturing techniques have enabled the fabrication of micro-light emitting diodes (microLEDs), with each LED having a pitch on the order of a few microns to a fraction of a micron. See, for example, International Patent Publication Number WO 2019/209945 A1, WO 2019/209957 A1, WO 2019/209961 A1, and WO 2020/210563 A1 to He et al., all of which are incorporated herein by reference in their entirety. Such microLEDs enable a host of new configurations for displays and other applications using light emitting elements.

A commonly implemented epitaxial layer structure for LEDs is shown in FIG. 1. A LED structure 100 includes a semiconductor substrate or template 110 supporting one or more bulk or prep layers 120. In an example, the semiconductor template is an n-type GaN template formed on an n-type epitaxial substrate. Active quantum wells (QWs) 130 are formed on bulk or prep layers 120. Bulk or prep layers 120 is, for example, a thick layer of a material or a structure of two or more materials configured for providing a thermal expansion coefficient transition and/or lattice match from semiconductor template 110 to active QWs 130. By adjusting the material composition of bulk or prep layers 120, more flexibility in the material selection for active QWs 130 can be obtained, thus enabling the formation of an active region with desired light emission characteristics. Finally, one or more p-layers 140 are deposited on active QWs 130 for providing electronic contact to LED structure 100. P-layers 140 include p-doped layers and/or a contact layer. LED structure 100 can then be etched or otherwise shaped to form the desired microLED form factor for a designated application.

In some implementations, a technique such as epitaxial growth and dry etching or selective area growth (SAG) may be used to define the position, shape, and size of LED structure 100 on semiconductor template 110. That is, one way to form an array of microLEDs on a substrate is to epitaxially grow the required layer structure for light emission (e.g., lattice matching or strain-management prep layers, active quantum well layers, electron blocking layers, p-layers, and other functional layers as shown in FIG. 1), then using a masked etch process (e.g., dry etch or wet etch) to shape and isolate the desired array of microLEDs from the layer structure. The etch normally includes etching through the layer structure, including the active light emission regions, to isolate the active light emission region of each microLED from the surrounding microLEDs.

This traditional process for microLED fabrication has disadvantages, such as wavelength shift and reduction in quantum efficiency from the pre-etch, pre-isolation LED layer structure. Accordingly, techniques and devices are presented herein that enable effective and efficient design and fabrication of microLEDs.

### SUMMARY OF THE DISCLOSURE

The following presents a simplified summary of one or more aspects in order to provide a basic understanding of such aspects. This summary is not an extensive overview of all contemplated aspects, and is intended to neither identify key or critical elements of all aspects nor delineate the scope of any or all aspects. Its purpose is to present some concepts of one or more aspects in a simplified form as a prelude to the more detailed description.

In an aspect of the present disclosure, a light emission system is described. The light emission system includes an array of micro light-emitting diodes (microLED)s. The array of microLEDs includes a semiconductor substrate, at least one prep layer formed on at least a portion of the semiconductor substrate, and an active region formed on the at least one prep layer. The array of microLEDs also include a plurality of thick sub-structures forming an array on the active region, and a plurality of thin sub-structures formed on the active region, each one of the plurality of thin sub-structures being located between each adjacent pair of thick substructures. Each one of the plurality of thick sub-structures defines a shape and size of a corresponding one of the microLEDs. Each one of the plurality of thin sub-structures is configured for preventing mobility of free electron carriers therethrough to electrically isolate each one of the thick sub-structures from every other one of the thick sub-structures. Further, the plurality of microLEDs share the active region.

In another aspect, a method for fabricating an array of micro light-emitting diodes (microLEDs) on a semiconductor substrate is described. The method includes depositing at least one prep layer on at least a portion of the semiconductor substrate, forming an active region on the at least one prep layer, depositing at least one p-layer on the active region, and depositing at least one mask structure on the p-layer, the at least one mask structure being configured for defining a size and shape of each one of the plurality of microLEDs. The method further includes partially etching away the at least one p-layer where the at least one p-layer is not covered by the at least one mask structure, and removing the at least one mask structure.

### BRIEF DESCRIPTION OF THE DRAWINGS

The appended drawings illustrate only some implementation and are therefore not to be considered limiting of scope.

FIG. 1 illustrates an example of a commonly implemented microLED structure, in accordance with aspects of this disclosure.

FIG. 2 illustrates a top view of a portion of a LED array including multiple microLED structures as part of an array for use in a display, in accordance with aspects of this disclosure.

FIG. 3 shows a cross-sectional view of an epitaxial layer structure for an LED, in accordance with aspects of this disclosure.

FIG. 4 illustrates a cross-sectional view of a plurality of microLEDs formed from selectively etching an epitaxial layer structure for an LED, in accordance with aspects of this disclosure.

FIG. 5 illustrates a cross-sectional view of a plurality of microLEDs formed from selectively etching an epitaxial layer structure for an LED, in accordance with aspects of this disclosure.

FIG. 6 shows a process for forming microLEDs, in accordance with aspects of this disclosure.

FIGS. 7-10 illustrate an alternative process for forming microLEDs, in accordance with aspects of this disclosure.

FIG. 11 illustrates a cross-sectional view of a plurality of microLEDs, in accordance with aspects of this disclosure.

### DETAILED DESCRIPTION

The detailed description set forth below in connection with the appended drawings is intended as a description of various configurations and is not intended to represent the only configurations in which the concepts described herein may be practiced. The detailed description includes specific details for the purpose of providing a thorough understanding of various concepts. It will be apparent to those skilled in the art that these concepts may be practiced without these specific details. In some instances, well known components are shown in block diagram form in order to avoid obscuring such concepts.

The present disclosure provides aspects of LEDs that enable light emission with improved efficiency and desired wavelength range, including at various wavelengths in the visible spectrum, including red, green, and blue wavelengths. The aspects presented herein enable applications of microLED technology that maintain high efficiency and specified wavelength range emission at reduced device sizes. In some examples, the light emitters may have a size on a micron scale or even a sub-micron scale.

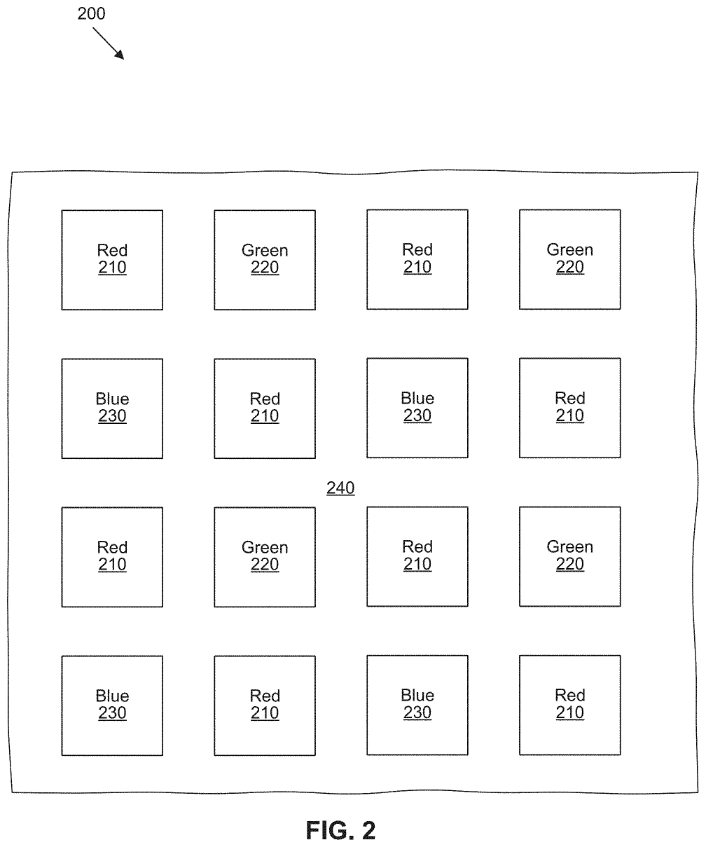

FIG. 2 illustrates a top view of a portion of a LED array 200 including multiple microLED structures as part of an array for use in a display, in accordance with aspects of this disclosure. As shown in FIG. 2, LED array 200 includes a plurality of microLED structures 210, 220, and 230 supported on a substrate 240 and, as an example, emitting at red, green, and blue wavelengths, respectively. Alternatively, all of the microLED structures may emit light within a single wavelength range, such as in the red wavelength range. While only a 4-by-4 array of LEDs is shown in FIG. 2, LED array 200 may be part of a larger array of emitters forming, for instance, a display, and the arrangement of the pixels, their shapes, their numbers, their sizes, and their corresponding wavelength emissions can be adjusted for specific applications. For instance, in specific applications, circular or hexagonal emitters may be implemented, and the emitters may be grouped together in groups of two, three, or more. The display can be a high resolution, high density display, such as those used in light field applications.

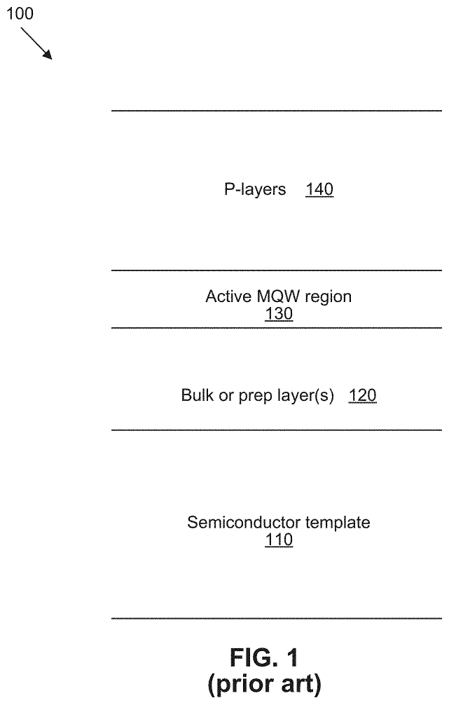

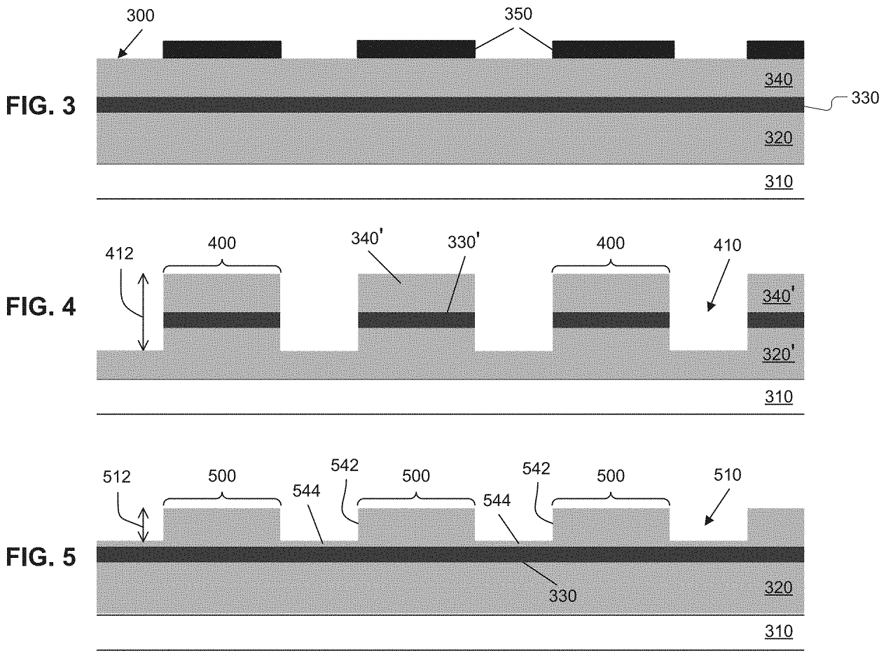

In order to define and shape the microLED structures in FIG. 2, a process such as the planar epitaxial deposition then etch described above may be used. As an example, FIG. 3 shows a cross-sectional view of an epitaxial layer structure 300 for an LED. Epitaxial layer structure is essentially a simplified, larger planar version of microLED structure 100 shown in FIG. 1. As shown in FIG. 3, epitaxial layer structure 300 includes a semiconductor substrate or template 310 supporting one or more prep layers 320 thereon. On prep layers 320, an active region 330 is formed via, for example, epitaxial deposition. In embodiments, active region 330 includes one or more quantum wells, quantum dots, or double heterojunction structures configured for light emission therefrom. In certain embodiments, active region 310 is an example of active QW region 130. A p-layer 340 is formed on top of active region 330. Each of semiconductor substrate 310, prep layers 320, active region 330, and p-layer 340 may include a plurality of layers therein, the plurality of layers potentially incorporating a variety of material compositions.

To define and shape an array of microLED structures from epitaxial layer structure 300, a dry or wet etch process may be used. For instance, a mask 350 may be deposited, printed, or formed on epitaxial layer structure 300 over the areas corresponding to the microLED structures. Then, a dry or wet etch process is used to remove the portions of epitaxial structure 300 that are not protected by mask 350 to a specific depth, thus shaping and isolating a plurality of microLED structures from epitaxial layer structure 300. In embodiments, mask 350 is one or more material layers that includes a patterned array of apertures therethrough.

The result of a traditional etch process is shown in FIG. 4. FIG. 4 shows a cross-sectional view of a plurality of microLEDs 400 (indicated by a bracket) separated by openings 410 etched to a depth 412 (indicated by a double-headed arrow) as resulting from selectively etching an LED epitaxial layer structure such as that shown in FIG. 3. In forming microLEDs 400, depth 412 of openings 410 extends into prep layers 320′, thus separating active region 330′ and p-layers 340′, in the traditional method described above. While separation of p-layers 340′ for each microLED 400 is required for being able to individually electronically address each microLED 400, it has been demonstrated that etching into prep layers 320′ thus separating the active regions results in a reduction in the internal quantum efficiency (IQE) and a blue shift (i.e., a shift in the emission wavelength toward shorter wavelengths) of the resulting microLED 400 as compared to epitaxial layer structure 300.

In contrast, FIG. 5 illustrates cross-sectional view of a plurality of microLEDs formed using an alternative method for isolating microLEDs from an epitaxial layer structure as shown in FIG. 3, in accordance with an embodiment. As shown in FIG. 5, microLEDs 500 (indicated by a bracket) are formed by etching openings 510, etched to a depth 512 (indicated by double-headed arrow). In other words, openings 510 are etched into what was formerly p-layers 340 to form thick sub-structures 542, which define the size and shape of individual microLEDs 500, and thin sub-structures 544 in openings 510. Thick sub-structures 542 are configured for electrically addressing individual microLEDs 500, and thin sub-structures 544 are configured for preventing mobility of fee carriers therethrough, while active region 330 and prep layers 320 are kept intact. In this way, microLEDs 500 maintain the IQE and emission wavelength of the original epitaxial layer structure 300 of FIG. 3, while having the form factor of microLEDs and operating as separate, individually-addressable microLEDs. Additionally, microLEDs 500 including intact active region 330 and prep layers 320 have been demonstrate much higher light extraction efficiency (LEE) over microLEDs 400 of FIG. 4 with separated active region 330′ and p-layers 340′.

Dimensions of openings 510 shown in FIG. 5 may be tailored according the spacing required between microLEDs 500 for the specific application. For instance, the spacing between microLEDs 500 may be on the order of a fraction of a micron (e.g., for high density microLED applications) to several microns (e.g., for applications requiring additional structures between microLEDs 500) or even wider (e.g., for low density microLED applications). Also, in certain embodiments, only a portion of a given semiconductor substrate includes microLEDs formed in the manner illustrated in FIGS. 3 and 5, thus leaving real estate on the semiconductor substrate for different types of processing or device fabrication.

As a specific example, a 0.5 micron layer of p-layers 340 left on top of active region 330 as thin sub-structures 544 has been demonstrated to be sufficient to ensure thin sub-structures 544 in openings 510 are depleted of free electron carriers, thus electrically isolating each microLED 500 from each other. For instance, p-layers 340 may be formed of p-type materials including an Al(In)GaN electron blocking layer (EBL). Thus, the p-layers are shaped into an array of sub-structures defining the shape and size of the microLED. Subsequently, each p-layer sub-structure corresponding to each microLED 500 can be individually accessed to be able to independently control each microLED 500, microLEDs 500 share an uninterrupted active QW structure, and the light emission performance of the original planar LED structure of epitaxial layer structure 300 is maintained. Such a structure may be formed, for example, by performing a shallow etch on the structure illustrated in FIG. 3, then stopping the etch process before reaching active region 330.

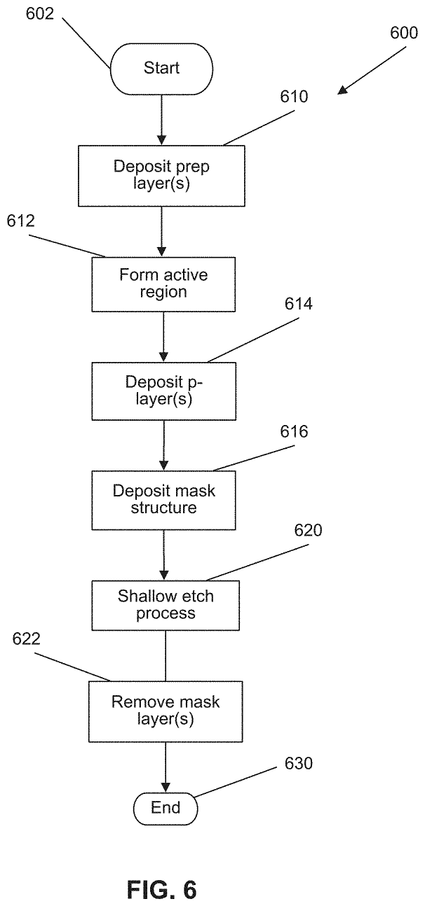

FIG. 6 shows a process for forming microLEDs on a semiconductor substrate or template, in accordance with an embodiment. As shown in FIG. 6, process 600 begins with a start step 602, then the prep layer(s) are deposited on a semiconductor substrate or template in a step 610. An active region is formed on the prep layers in a step 612, followed by deposition of p-layers in a step 614. One or more mask structure for defining the size and shape of each microLED to be formed is deposited on the p-layers in a step 616. A shallow etch process is then performed in a step 620 to form the microLEDs, then the mask structure is removed in a step 622. Process 600 ends with an end step 630.

Step 620 may include, for example, monitoring the layer structure being etched to ensure the etching is stopped before the active region is exposed. For instance, step 620 may include an accurate etch depth monitoring (e.g., optical or other sensing arrangement) for stopping the etch at a specific known depth so as to not etch into the active region. As an alternative, if the prep layers includes a particular layer (such as an electron blocking layer) formed of a specific known material, the etching apparatus may be configured for monitoring for that materials (e.g., using optical or other sensing arrangements) to indicate the etch process should be stopped when that specific known material is sensed.

It is noted that shallow etch processes are known in transistor technologies, such as with heterojunction bipolar transistors (HBTs). For instance, the use of a passivation ledge in the formation of HBTs has been discussed in literature (see, for example, https://parts.jpl.nasa.gov/mmic/3-V.PDF accessed 2020 Dec. 21). However, this type of etch manipulation for forming microLEDs is not currently used.

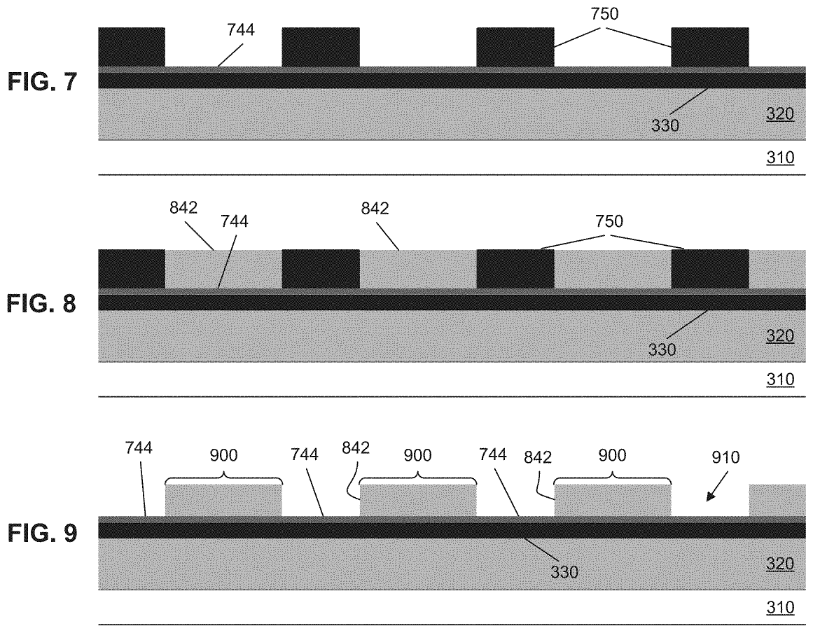

An alternative microLED array structure is illustrated in FIGS. 7-9. As shown in FIG. 7, semiconductor substrate or template 310 supports prep layer(s) 320 and active region 330 thereon. Then, rather than depositing a p-layer structure directly on the active region, an electron blocking layer 744 is deposited on active region 330. A mask 750 is then formed on electron blocking layer 744 to define the shape and size of the microLEDs to be formed. In an example, mask 750 is essentially a negative of mask 350 of FIG. 3. In embodiments, mask 750 is one or more material layers that includes a patterned array of apertures therethrough, where the size and shape of each aperture at least in part define the size and shape of the microLEDs to be formed.

Referring to FIG. 8, p-layer(s) 842 is deposited on electron blocking layer 744. P-layer(s) 842 can be configured for cooperating with electron blocking layer 744 for defining the shape and size of microLEDs while enabling individual addressing of each microLED via p-layer(s) 842. Then, as shown in FIG. 9, once mask structure 750 is removed, microLEDs 900 separated by openings 910 remain. Like microLEDs 500 of FIG. 5, microLEDs 900 share an uninterrupted active region while still being individually addressable via p-layer(s) 842 and electron blocking layer 744 preventing free electron carrier migration between neighboring microLEDs 900. Thus, the integrity of prep layers 320 and active region 330 are kept intact, thus preserving the IQE and emission wavelength of the original planar structure while defining individually addressable microLEDs.

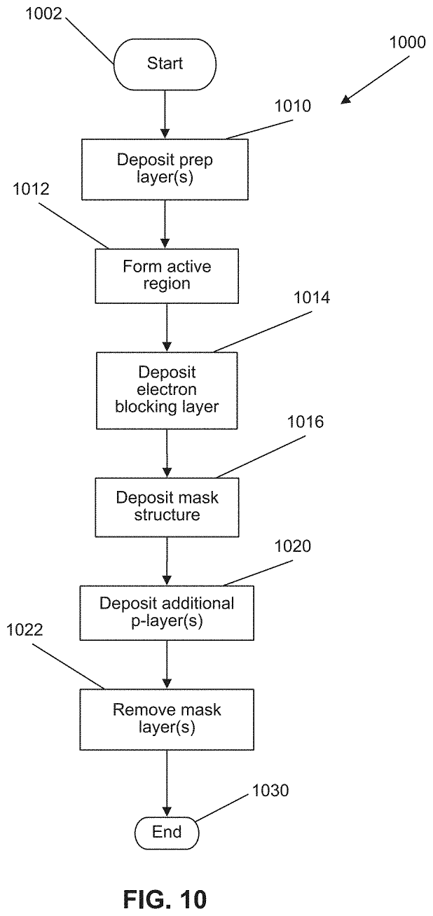

FIG. 10 shows an alternative process for forming microLEDs on a semiconductor substrate or template such as illustrated in FIGS. 7-9, in accordance with aspects of this disclosure. As shown in FIG. 10, a process 1000 begins with a start step 1002, and proceeds to a step 1010 to deposit one or more prep layers onto a semiconductor substrate or template. Then, an active region (e.g., an active QW region) is formed on the prep layers in a step 1012. An electron blocking layer is deposited on the active region in a step 1014. In a step 1016, one or more mask structures for defining the shape and size of the microLEDs is deposited on the electron blocking layer. Then, additional p-layers are deposited in a step 1020. The mask structure is removed in a step 1022, and process 1000 terminates with an end step 1030.

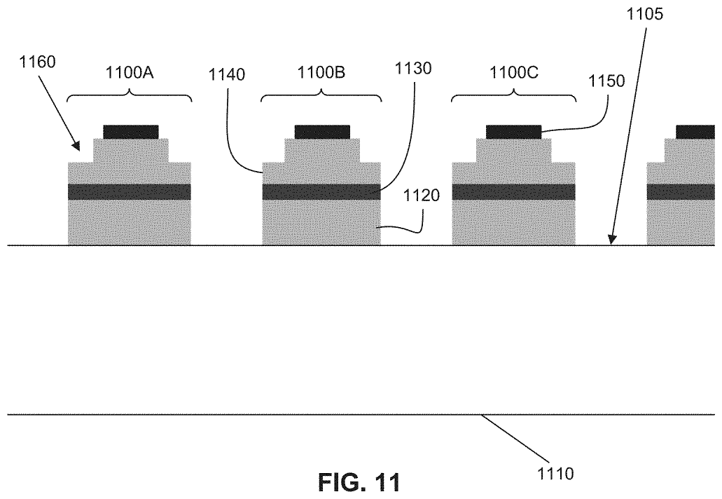

FIG. 11 shows an alternative arrangement of microLEDs formed on a semiconductor substrate or template, in accordance with aspects of this disclosure. As shown in FIG. 11, a plurality of microLEDs 1100A-1100C, separated by spacing 1105, are formed on a semiconductor substrate or template 1110. Within each one of microLEDs 1100A-1100C, there is one or more prep layers 1120, an active region 1130, and one or more p-layers 1160. Each one of microLEDs 1100A-1100C is also shown with an electrical contact 1150 for electrically addressing that microLED. It is noted that, while spacings 1105 are shown as separating adjacent microLEDs, including active regions 1130, and extending into semiconductor substrate 1110, each one of microLEDs 1100A-1100C also includes shallow steps 1160. In this way, while the dimensions of the light emitting portion of each microLED (i.e., active region 1130) may be maximized while the device real estate required for electrical addressing of each one of microLEDs 1100A-1100C can be tailored for the requirements of the specific device application. Further, in the configuration shown in FIG. 11, all of the microLEDs may be configured for emitting light in the same wavelength range, or each one of microLEDs 1100A-1100C can be configured for emitting at a distinct wavelength. For instance, microLED 1100A may be configured for emitting light in a red wavelength, microLED 1100B may be configured for emitting light in a green wavelength, and microLED 1100C may be configured for emitting light in a blue wavelength. Shallow steps 1160 may be incorporated into all of microLEDs 1100A-1100C, or only in certain microLEDs.

The techniques discussed above may be used in configurations where multiple types of microLEDs (e.g., configured for emitting light at different wavelength ranges) are monolithically integrated on a common substrate. In such an embodiment, one or more of the microLEDs may be based on the shallow isolation structure formed by the shallow etch process described above. Further, the shallow isolation structure may be combined with the traditional deep isolation structures (e.g., as shown in FIG. 4) for different types of microLEDs. Such deep isolation structures may be used, for example, outside of shallow isolation areas. Such a combination of shallow and deep isolation structures may be optimized for specific desired characteristics for the microLEDs, such as optical isolation and light extraction.

While the techniques described above may be particularly attractive for the formation of microLEDs operating in a red wavelength range, the same techniques may be used for the formation of microLEDs operating in other wavelength ranges, such as in the blue, green, infrared, and other wavelength ranges. That is, aspects of the microLED structure presented herein enable higher efficiencies at a broader range of wavelengths. For example, the aspects presented herein may improve efficiency at longer wavelengths of light emission while minimizing blue shift from the planar LED structure to the microLED format. It is noted that the device configurations and techniques disclosed herein may be applicable to any semiconductor QW structures and devices.

Moreover, the shallow etch techniques described above may be used in combination with other microLED formation techniques. For instance, additional microLEDs may be formed in the openings between the microLEDs (e.g., openings 510 and 910) formed using shallow etch techniques. As an example, a first set of microLEDs operating in a first wavelength range can be formed using the shallow etch technique described above, leaving sufficient space between the first set of microLEDs for forming additional microLEDs in the openings. The additional microLEDs may be configured to cooperate with the active region of the first set of microLEDs to emit light in a wavelength range outside of the first wavelength range. Alternatively, additional semiconductor devices (e.g., sensors, transistors, or other devices that do not emit light) may be disposed in the openings between microLEDs formed using the shallow etch techniques described above.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but is to be accorded the full scope consistent with the language claims, wherein reference to an element in the singular is not intended to mean “one and only one” unless specifically so stated, but rather “one or more.” Unless specifically stated otherwise, the term “some” refers to one or more. Combinations such as “at least one of A, B, or C,” “one or more of A, B, or C,” “at least one of A, B, and C,” “one or more of A, B, and C,” and “A, B, C, or any combination thereof” include any combination of A, B, and/or C, and may include multiples of A, multiples of B, or multiples of C. Specifically, combinations such as “at least one of A, B, or C,” “one or more of A, B, or C,” “at least one of A, B, and C,” “one or more of A, B, and C,” and “A, B, C, or any combination thereof” may be A only, B only, C only, A and B, A and C, B and C, or A and B and C, where any such combinations may contain one or more member or members of A, B, or C. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims.

What is claimed is:

1. A light emission system comprising:
an array of micro light-emitting diodes (microLEDs including:
a semiconductor substrate;
at least one prep layer formed on at least a portion of the semiconductor substrate;
an active region formed on the at least one prep layer;
a plurality of thick sub-structures forming an array on the active region; and
a plurality of thin-substructures formed on the active region, each one of the plurality of thin sub-structures being located between a respective adjacent pair of thick sub-structures,
wherein each one of the plurality of thick sub-structures defines a shape and size of a corresponding one of the microLEDs in the array of microLEDs,
wherein each one of the plurality of thin sub-structures is configured for preventing mobility of free electron carriers therethrough to electrically isolate each one of the thick sub-structures from every other one of the thick sub-structures, and
wherein the plurality of microLEDs share the active region.

2. The light emission system of claim 1, wherein the each one of the plurality of thin sub-structure includes an electron blocking layer.

3. The light emission system of claim 2, wherein each one the thin sub-structure is formed of a p-type Al(In)GaN.

4. The light emission system of claim 2, wherein each one of the thin sub-structure is less than one micron in thickness.

5. The light emission system of claim 4 wherein each one of the thin sub-structure is approximately 0.5 microns in thickness.

6. The light emission system of claim 1, wherein the active region includes at least one of a quantum well structure, a plurality of quantum dots, and a double heterojunction structure.

7. A method for fabricating an array of micro light-emitting diodes (microLEDs) on a semiconductor substrate, the method comprising:
depositing at least one prep layer on at least a portion of the semiconductor substrate;
forming an active region on the at least one prep layer;
depositing at least one p-layer on the active region;
depositing at least one mask structure on the p-layer, the at least one mask structure being configured for defining a size and shape of each one of the plurality of microLEDs;
thinning regions of at least one p-layer not covered by the at least one mask structure; and
removing the at least one mask structure.

8. The method of claim 7, wherein partially etching away the at least one p-layer includes, where the at least one p-layer is not covered by the at least one mask structure, reducing a thickness of the at least one p-layer to less than one micron.

9. The method of claim 8, wherein reducing the thickness of the at least one p-layer includes, where the at least one p-layer is not covered by the at least one mask structure, reducing the thickness of the at least one p-layer to approximately 0.5 micron.

10. The method of claim 7,
wherein a combination of the semiconductor substrate, the at least one prep layer, the active region, and the at least one p-layer exhibits light emission in a first wavelength range, and
wherein each one of the microLEDs, after removing the at least one mask structure, exhibits light emission in the first wavelength range.

11. The method of claim 7,
wherein a combination of the semiconductor substrate, the at least one prep layer, the active region, and the at least one p-layer exhibits a first internal quantum efficiency (IQE) value at a given wavelength, and
wherein each one of the microLEDs, after removing the at least one mask structure, exhibits an IQE value substantially similar to the first IQE at the given wavelength.

12. The method of claim 7, wherein partially etching away the at least one p-layer leaves intact the active region and the at least one prep layer.

13. The method of claim 7, wherein forming an active region includes forming at least one of a quantum well structure, a plurality of quantum dots, and a double heterojunction structure.

14. A light emission system comprising:
an array of micro light-emitting diodes (microLEDs) including:
a semiconductor substrate;
at least one prep layer formed on at least a portion of the semiconductor substrate;
an active region formed on the at least one prep layer;
an electron blocking layer formed on the active region; and
a plurality of thick sub-structures forming an array on the electron blocking layer,
wherein each one of the plurality of thick sub-structures is physically separate from every other one of the plurality of thick sub-structures and defines a shape and size of a corresponding one of the microLEDs,
wherein the electron blocking layer is configured for preventing mobility of free electron carriers therethrough to electrically isolate each one of the thick sub-structures from every other one of the thick sub-structures, and
wherein the array of microLEDs share the active region.

15. A method for fabricating an array of micro light-emitting diodes (microLEDs) on a semiconductor substrate, the method comprising:
depositing at least one prep layer on at least a portion of the semiconductor substrate;
forming an active region on the at least one prep layer;
depositing an electron blocking layer on the active region;
depositing at least one p-layer on the electron blocking layer;
depositing at least one mask structure on the p-layer, the at least one mask structure being configured for defining a size and shape of each one of the microLEDs;
etching away the at least one p-layer without penetrating through the electron blocking layer where the at least one p-layer is not covered by the at least one mask structure; and
removing the at least one mask structure.
